(19) United States
(12) Patent Application Publication
(10) Pub. No.: US 2019/0292407 A1
(43) Pub. Date: Sep. 26, 2019

(54) POLISHING COMPOSITION, METHOD FOR PRODUCING POLISHING COMPOSITION, AND POLISHING METHOD

(71) Applicant: FUJIMI INCORPORATED, Kiyosu-shi, Aichi (JP)

(72) Inventors: Shota SUZUKI, Kiyosu-shi, Aichi (JP); Yoshihiro IZAWA, Kiyosu-shi, Aichi (JP)

(73) Assignee: FUJIMI INCORPORATED, Kiyosu-shi, Aichi (JP)

(21) Appl. No.: 16/317,625

(22) PCT Filed: Jun. 12, 2017
(86) PCT No.: PCT/JP2017/021695

§ 371 Date: Jan. 14, 2019

(30) Foreign Application Priority Data
Jul. 15, 2016 (JP) 2016-140629

(51) Int. Cl. C09G 1/02; B24B 37/04; C09K 3/14; H01L 21/3105; H01L 21/306; H01L 21/321

(52) U.S. Cl. CPC C09G 1/02; B24B 37/044; H01L 21/3212; H01L 21/31053; H01L 21/30625; C09K 3/1463

(57) ABSTRACT

The present invention provides a polishing composition which polishes an object to be polished at a high polishing speed and with less scratches (defects).

The present invention is a polishing composition including silica having a maximum peak temperature of 30° C. or higher and 53° C. or lower in a weight change rate distribution curve obtained by thermogravimetric measurement in a range of 25° C. or higher and 250° C. or lower, and having a pH at 25° C. of less than 6.0.

### TECHNICAL FIELD

The present invention relates to a polishing composition, a method for producing a polishing composition, and a polishing method.

### BACKGROUND ART

In recent years, along with multilayer wiring of semiconductor substrate surfaces, so-called chemical mechanical polishing (CMP), which is a technique of flattening a semiconductor substrate by polishing, is used in the production of devices. CMP is a method for flatting the surface of an object to be polished such as a semiconductor substrate using a polishing composition (slurry) including abrasive grains such as silica, alumina, and ceria, an anticorrosive, and a surfactant, wherein the object to be polished is, for example, silicon, polysilicon, a silicon oxide film (silicon oxide), silicon nitride, a wire or a plug made of a metal or the like.

For example, as a CMP slurry for polishing a substrate including oxygen atoms and silicon atoms such as silicon oxide, JP 2001-507739 A (corresponding to U.S. Pat. No. 5,759,917 B) discloses an aqueous chemical mechanical polishing composition including a salt, soluble cerium, carboxylic acid, and silica (especially fumed silica). Additionally, JP 2015-063687 A (corresponding to U.S. Pat. No. 9,012,327 B) discloses a chemical mechanical polishing composition including water, 0.1 to 40% by weight of colloidal silica particles, and 0.001 to 5% by weight of an additive (pyridine derivative).

### SUMMARY OF INVENTION

However, the aqueous chemical mechanical polishing composition described in JP 2001-507739 A (corresponding to U.S. Pat. No. 5,759,917 B) improves the polishing speed of the substrate, but causes many scratches on the substrate surface.

Additionally, the chemical mechanical polishing composition described in JP 2015-063687 A (corresponding to U.S. Pat. No. 9,012,327 B) reduces scratches on the substrate surface, but cannot achieve a sufficient polishing speed.

Thus, in polishing of an object to be polished containing oxygen atoms and silicon atoms, demanded is a polishing composition which can solve a contradictory problem, that is, the improvement of the polishing speed and the reduction of scratches (defects).

Accordingly, the present invention has been accomplished in view of the above-described problem, and an object of the present invention is to provide a polishing composition which polishes an object to be polished (in particular, an object to be polished containing oxygen atoms and silicon atoms) at a high polishing speed, and reduces scratches (defects) on the surface of the object to be polished.

In order to solve the above-described problem, the inventors carried out dedicated research. As a result of this, they found that the above-described problem is solved with a polishing composition including silica having a maximum peak temperature within a specified range in a weight change rate distribution curve obtained by thermogravimetric measurement in a range of 25° C. or higher and 250° C. or lower, and having a pH of less than 6.0.

That is, the above-described object can be achieved by a polishing composition including silica having a maximum peak temperature of 30° C. or higher and 53° C. or lower in a weight change rate distribution curve obtained by thermogravimetric measurement in a range of 25° C. or higher and 250° C. or lower, and having a pH at 25° C. of less than 6.0.

### BRIEF DESCRIPTION OF DRAWINGS

FIG. 1 is a schematic view for illustrating the action of abrasive grains on an object to be polished.

FIG. 2 is a weight change rate distribution curve obtained by thermogravimetric measurement on the abrasive grains used in Examples and Comparative Examples.

### DESCRIPTION OF EMBODIMENTS

One aspect of the present invention is a polishing composition including silica having a maximum peak temperature of 30° C. or higher and 53° C. or lower in a weight change rate distribution curve obtained by thermogravimetric measurement in a range of 25° C. or higher and 250° C. or lower, and a pH at 25° C. of less than 6.0. The polishing composition having this configuration polishes an object to be polished (especially an object to be polished containing an oxygen atom(s) and a silicon atom(s)) at a high polishing speed, and reduces scratches (defects) on the surface of an object to be polished.

In the present description, a maximum peak in a weight change rate distribution curve obtained by thermogravimetric measurement in a range of 25° C. or higher and 250° C. or lower of silica may be referred to as “TG peak”. Additionally, the bottom temperature of the maximum peak (TG peak) is referred to as “maximum peak temperature” or “TG peak temperature”.

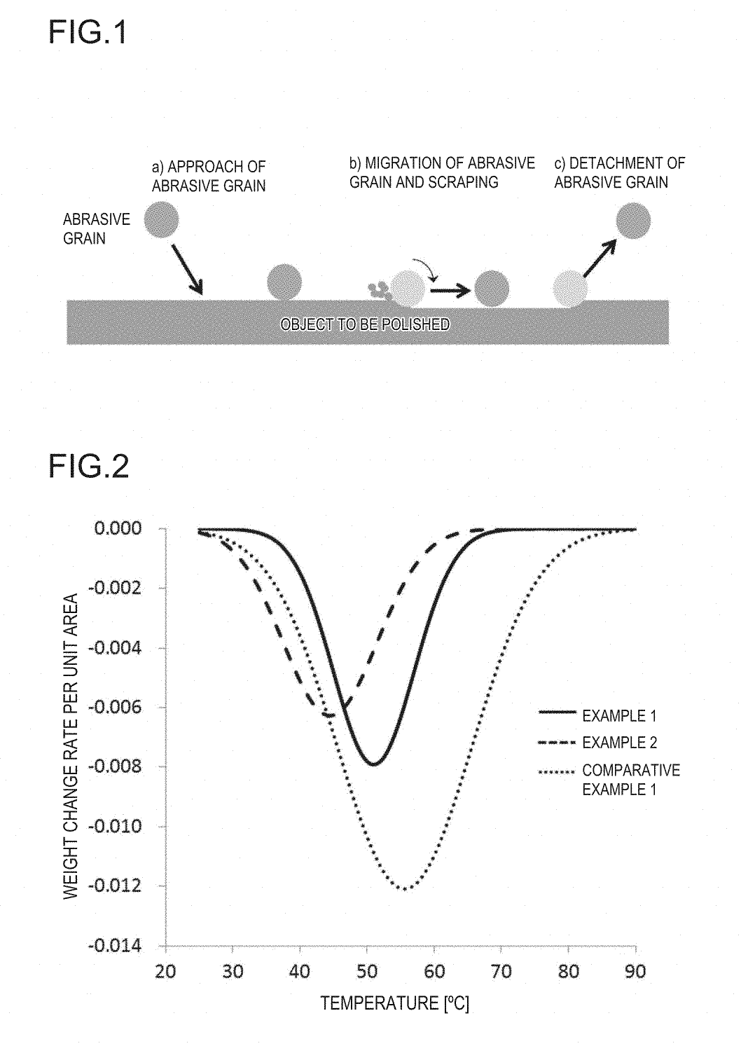

Semiconductor devices increasingly have multilayer structures, so that development of a technique for polishing an interlayer insulating film (for example, a SiO₂ film) at a higher polishing speed is demanded. In general, the mechanical action of abrasive grains to polish an object to be polished is based on the following mechanism. More specifically, as depicted in FIG. 1, abrasive grains approach an object to be polished (a) in FIG. 1)). In the next place, the abrasive grains migrate on the object to be polished, whereby the substrate surface is scraped (polished) (b) in FIG. 1)), finally the abrasive grains detach from the object to be polished (c) in FIG. 1)). Among the above-described actions, in prior art, in order to achieve a high polishing speed, attention was directed toward the process of the approach of the abrasive grains to an object to be polished (a) in FIG. 1)), and the improvement of polishing by the action of abrasive grains was attempted by increasing the frequency of approach and/or contact of abrasive grains to an object to be polished. As a method for increasing the frequency of approach and/or contact of abrasive grains to an object to be polished, for example, suggested are the increase of the number of abrasive grains, the increase of the size of abrasive grains, the use of different shapes of abrasive grains, the use of abrasive grains having a zeta potential which has a different sign from that of an object to be polished, and the addition of a salt for decreasing the absolute values of the zeta potential of abrasive grains and an object to be polished. However, it is difficult to sufficiently satisfy the recent demand for higher polishing speeds and the reduction of scratches (defects) with mere combination of the above-described existing techniques.

In order to solve the above-described problems, the inventors carried out dedicated research. As a result of this, it was found that both of a high polishing speed and reduction of scratches (defects) can be achieved by using silica (abrasive grains) which exhibits specific behavior in thermogravimetric analysis, and adjusting the pH of the polishing composition at a relatively low value. The estimated mechanism is described below using a silica dispersion including water as a dispersion medium as an example, without limiting the technical scope of the present invention.

It is considered that a film of dispersion medium molecules (water molecules) is formed on the surface of the silica particles included in the polishing composition through, for example, hydrogen bonding by surface silanol groups. When silica having such dispersion medium molecule (water molecule) film is subjected to thermogravimetric (TG) analysis, with the increase of the heating temperature (measurement temperature) from the initiation temperature around room temperature, the decrease of weight likely due to evaporation of the dispersion medium (for example, water) covering the particle surface is observed, and further increase of the temperature causes a behavior of particle growth due to the formation of aggregates by dehydration condensation between silanol groups, and fusion between particles. Among them, the decrease of weight by evaporation of the dispersion medium (for example, water) covering the particle surface is considered to occur usually 250° C. or lower, so that the maximum peak (TG peak) in a range of 25° C. or higher and 250° C. or lower in the present invention is likely due to evaporation of the dispersion medium (for example, water) covering the particle surface. Accordingly, it is considered that the low peak temperature reflects easiness of loss of the dispersion medium (for example, water) covering the particle surface from the particle surface (weakness of affinity between the abrasive grain surface and the dispersion medium molecules). When such silica which tends to lose a dispersion medium molecular film (affinity between the abrasive grain surface and the dispersion medium molecules is weak, so the TG peak temperature is low) is included in a polishing composition, a dispersion medium molecular film is hardly present between the silica (abrasive grain) surface and an object to be polished during polishing, which facilitates the access of silica to the object to be polished. Therefore, even the silica is in a small amount (low concentration), the silica efficiently (at a high frequency) approaches an object to be polished, and efficiently scrapes (polishes) the surface of the object to be polished. In particular, in polishing of an object to be polished containing an oxygen atom and a silicon atom such as tetraethyl orthosilicate (TEOS), when a dispersion medium molecular film (for example, a water molecular film) is tend to be lost (affinity between the abrasive grain surface and the dispersion medium molecule is weak, so the TG peak temperature is low), silica particles easily approach the surface of the object to be polished during polishing, so that the silanol groups on the silica surface and the silanol groups on the surface of the object to be polished are easily bonded together. Furthermore, it is considered that charge interaction is present besides hydrogen bonding between the silica particles and the surface of an object to be polished. In the present invention, charge interaction between silica particles and the surface of an object to be polished is likely favorably achieved by adjusting the pH of the composition to less than 6.0. As a result of this, the time of migration of silica particles on the surface of an object to be polished is prolonged. Accordingly, the time of detachment of silica particles from an object to be polished is long, so that silica particles scrape (polish) the substrate surface for a longer time (more efficiently), which improves the polishing speed. Additionally, as described above, the moving distance of silica particles on the surface of an object to be polished is long, which allows scraping off (removal) of the scratches exist on the surface of an object to be polished. Therefore, it is considered that the polishing speed is improved and, scratches (defects) are reduced when the TG peak temperature of silica is low and the pH of the polishing composition is less than 6.0.

In the polishing composition according to an aspect of the present invention, silica (abrasive grains) likely readily approaches an object to be polished and resides on the surface of the object to be polished for a long time, so that silica polishes the object to be polished at a high polishing speed even the silica concentration is low, which further reduces the occurrence of scratches (defects), and is preferred from the viewpoint of cost.

The present invention is described below in detail. Unless otherwise specified, operations and measurements of physical properties and the like are carried out at room temperature (20 to 25° C.)/relative humidity 40 to 50% RH. In the present description, “X to Y” representing a certain range include X and Y, and means “X or more and Y or less”.

<Polishing Composition>

The polishing composition according to an aspect of the present invention includes silica having a maximum peak temperature of 30° C. or higher and 53° C. or lower in a weight change rate distribution curve obtained by thermogravimetric measurement in a range of 25° C. or higher and 250° C. or lower, and has a pH at 25° C. of less than 6.0.

“Thermogravimetric measurement” is a method wherein a sample weight is continuously measured while increasing a heating temperature at a constant rate, and tracking a weight change of the sample caused by heating, thereby analyzing thermal properties of the sample. In the present description, “thermogravimetric measurement” is specifically carried out by the method described in Examples.

In the present description, “weight change rate distribution curve” is a curve drawn by plotting a weight change rate per unit area of the sample as the ordinate, and a measurement temperature (heating temperature) as the abscissa based on the result of weight change obtained by thermogravimetric measurement to obtain a weight change rate distribution, and Gaussian fitting the weight change rate distribution thus obtained. The weight change rate per unit area of the sample was specifically determined by the method described in Examples.

The polishing composition according to an aspect of the present invention includes silica having a maximum peak temperature of 30° C. or higher and 53° C. or lower in a weight change rate distribution curve obtained by thermogravimetric measurement in a range of 25° C. or higher and 250° C. or lower. The maximum peak (TG peak) in a range of 25° C. or higher and 250° C. or lower in a weight change rate distribution curve is considered as a weight change observed caused by evaporation (loss) of a dispersion medium molecular film (for example, water molecular film) exists on the silica surface. If the silica has a TG peak temperature of higher than 53° C. (more specifically, if the silica is hard to lose the dispersion medium molecular film), affinity between the silica and the dispersion medium is too high (for example, the water molecular film on the silica particle surface is too thick), the distance between silica particles and the surface of an object to be polished is too great, so that the silica and the surface of an object to be polished cannot sufficiently approach each other. As a result of this, the silica particles cannot reside on the surface of an object to be polished for a sufficient time, whereby the polishing efficiency (polishing speed) decreases. On the other hand, it is technically difficult to produce silica having a TG peak temperature of below 30° C. From the viewpoint of achieving a higher level of balance between the improvement of the polishing speed and the reduction of scratches (defects), the lower limit of the TG peak temperature of silica is preferably 35° C. or higher, more preferably 40° C. or higher, and even more preferably higher than 40° C. Additionally, from the viewpoint of achieving a higher level of balance between the improvement of the polishing speed and the reduction of scratches (defects), the upper limit of the TG peak temperature of silica is preferably below 53° C., more preferably 52° C. or lower, even more preferably below 50° C., yet even more preferably below 48° C., and most preferably below 46° C. In one preferred embodiment, the TG peak temperature of silica is 35° C. or higher and below 53° C., and in a more preferred embodiment, the TG peak temperature of silica is 40° C. or higher and 52° C. or lower, in an even more preferred embodiment, the TG peak of silica is higher than 40° C. and below 50° C., in a yet even more preferred embodiment, the TG peak of silica is higher than 40° C. and below 48° C., and in the most preferred embodiment, the TG peak of silica is higher than 40° C. and below 46° C. When the TG peak is within these ranges, both of the improvement of the polishing speed and the reduction of scratches (defects) are achieved with a high level of balance. In particular, when the TG peak is within the above-described ranges, a high polishing speed can be achieved even with a composition having a low silica content.

The above-described TG peak is likely attributable to the dispersion medium molecular film (water molecular film) formed on the silica surface, and thus can be controlled by any means such as modification of the surface condition of silica. In the present invention, silica is not particularly limited as long as its TG peak temperature is within the above-described range. For example, the TG peak temperature can be decreased by modifying the silica surface with hydrothermal treatment, or, for example, the TG peak can be enlarged by heating silica in a strong acid or strong alkali liquid. Using hydrothermal treatment (hydrothermal reaction) as an example, modification treatment of the silica surface condition is more specifically described below. Using hydrothermal treatment (hydrothermal reaction) as an example, modification treatment of the silica surface condition is more specifically described below.

In hydrothermal treatment (hydrothermal reaction), silica such as colloidal silica is charged together with water into a pressure proof container such as an autoclave. Hydrothermal reaction is carried out at, for example, 120° C. or higher and 300° C. or lower, and preferably 150° C. or higher and 180° C. or lower. At this time, the temperature rising rate is, for example, 0.5° C./minute or more and 5° C./minute or less. After the desired reaction temperature is reached, hydrothermal reaction is carried out for 0.1 hours or more and 30 hours or less, preferably 0.5 hours or more and 5.0 hours or less. The pressure during hydrothermal reaction is, for example, saturated water vapor pressure, more specifically, for example, 0.48 MPa or more and 1.02 MPa or less. After the desired reaction time is elapsed, it is preferred that the sample be immediately cooled, thereby preventing the progress of excessive hydrothermal treatment.

The polishing composition of the present invention essentially includes silica (silica particles) as abrasive grains, and more preferably include colloidal silica as abrasive grains. More specifically, according to a preferred embodiment of the present invention, the silica is colloidal silica. Examples of the method for producing colloidal silica include a sodium silicate method, a sol-gel method, and the like, and colloidal silica produced by any of these producing methods is favorably used. However, from the viewpoint of reduction of metal impurities, colloidal silica produced by a sol-gel method, which allows production at a high purity, is preferred.

The shape of the silica (abrasive grains) is not particularly limited, and may be spherical or non-spherical, but is preferably spherical.

The size of silica (abrasive grains) is not particularly limited. For example, the average primary particle size of silica (abrasive grains) is preferably 5 nm or more, more preferably 10 nm or more, and even more preferably 20 nm or more. With the increase of the average primary particle size of silica, the polishing speed of an object to be polished with the polishing composition increases. The average primary particle size of the silica is preferably 200 nm or less, more preferably 100 nm or less, and even more preferably 50 nm or less. With the decrease of the average primary particle size of silica, it becomes easy to obtain a surface with less defects and a low roughness by polishing using a polishing composition. The average primary particle size of silica (abrasive grains) is 5 nm or more and 200 nm or less in one preferred embodiment, 10 nm or more and 100 nm or less in a more preferred embodiment, and 20 nm or more and 50 nm or less in a particularly preferred embodiment. The average primary particle size of silica (diameter of silica particles (primary particles)) may be, for example, calculated based on the specific surface area (SA) of silica particles calculated by the BET method, on the assumption that the shape of the silica particles is spherical. In the present description, the average primary particle size of silica is the value measured by the method described in Examples.

The average secondary particle size of silica (abrasive grains) is preferably 25 nm or more, more preferably 35 nm or more, and even more preferably 55 nm or more. With the increase of the average secondary particle size of silica, resistance during polishing decreases, which allows stable polishing. The average secondary particle size of silica (abrasive grains) is preferably 1 μm or less, more preferably 500 nm or less, and even more preferably 100 nm or less. With the decrease of the average secondary particle size of silica (abrasive grains), the surface area of silica (abrasive grains) per unit mass increases, the frequency of contact with an object to be polished increases, and thus the polishing efficiency improves. The average secondary particle size of silica (abrasive grains) is 25 nm or more and 1 μm or less in one preferred embodiment, 35 nm or more and 500 nm or less in a more preferred embodiment, and 55 nm or more and 100 nm or less in a particularly preferred embodiment. In the present description, the average secondary particle size of silica is the value measured by the method described in Examples. The value of the degree of association (average secondary particle size/average primary particle size) calculated from these values is also not particularly limited, and, for example, 1.5 to 5.0, and preferably about 1.8 to 4.0.

For example, the density of silica (abrasive grains) depends on the producing method (for example, a sol-gel method or sodium silicate method). Additionally, even in one producing method (for example, a sol-gel method), the porosity varies depending on the reaction temperature and the time required for the reaction. The porosity likely influences the hardness of silica itself, so that it is preferred that its true density be grasped. The true density of silica (abrasive grains) is, in consideration of hardness of silica, preferably more than 1.70 g/cm³, more preferably 1.80 g/cm³ or more, even more preferably 1.90 g/cm³ or more, and particularly preferably 2.07 g/cm³ or more. According to a more preferred embodiment of the present invention, silica has a true density of 1.80 g/cm³ or more. According to a more preferred embodiment of the present invention, silica has a true density of 1.90 g/cm³ or more. According to a particularly preferred embodiment of the present invention, silica has a true density of 2.07 g/cm³ or more. The upper limit of the true density of silica is preferably 2.20 g/cm³ or less, more preferably 2.18 g/cm³ or less, and particularly preferably 2.15 g/cm³ or less. The true density of silica (abrasive grains) is more than 1.70 g/cm³ and 2.20 g/cm³ or less in a preferred embodiment, 1.80 g/cm³ or more and 2.18 g/cm³ or less in a more preferred embodiment, 1.90 g/cm³ or more and 2.15 g/cm³ or less in an even more preferred embodiment, and 2.07 g/cm³ or more and 2.15 g/cm³ or less in a particularly preferred embodiment. In the present description, the true density of silica (abrasive grains) is the value measured by the method described in Examples.

The BET specific surface area of silica (abrasive grains) is not particularly limited, and preferably 50 m²/g or more, more preferably 60 m²/g or more, and even more preferably 70 m²/g or more. The upper limit of the BET specific surface area of silica is preferably 120 m²/g or less, and more preferably less than 95 m²/g. From the viewpoint of the balance between improvement of the polishing speed and the reduction of scratches (defects), the BET specific surface area of silica (abrasive grains) is 50 m²/g or more and 120 m²/g or less in a preferred embodiment, 60 m²/g or more and less than 95 m²/g in a more preferred embodiment, and 70 m²/g or more and less than 95 m²/g in an even more preferred embodiment. In the present description, the BET specific surface area of silica (abrasive grains) is the value measured by the method described in Examples.

Additionally, silica may be surface-modified. When surface-modified silica is used as abrasive grains, the use of colloidal silica having an immobilized organic acid or an organic amine is preferred. Immobilization of an organic acid or an organic amine to the surface of colloidal silica included in the polishing composition is achieved by, for example, chemical bonding of a functional group of an organic acid or an organic amine to the surface of colloidal silica. Mere coexistence of colloidal silica and an organic acid or an organic amine cannot achieve immobilization of the organic acid or the organic amine to the colloidal silica. Immobilization of a sulfonic acid, which is an organic acid, to colloidal silica can be achieved by, for example, the method described in “Sulfonic acid-functionalized silica through quantitative oxidation of thiol groups”, Chem. Commun. 246-247 (2003). Specifically, a silane coupling agent having a thiol group such as 3-mercaptopropyltrimethoxysilane is coupled with colloidal silica, and then the thiol group was oxidized with hydrogen peroxide, thereby obtaining colloidal silica having a sulfonic acid immobilized on its surface. Alternatively, immobilization of a carboxylic acid on colloidal silica can be achieved by, for example, the method described in “Novel Silane Coupling Agents Containing a Photolabile 2-Nitrobenzyl Ester for Introduction of a Carboxy Group on the Surface of Silica Gel”, Chemistry Letters, 3, 228-229 (2000). Specifically, a silane coupling agent containing a photoreactive 2-nitrobenzyl ester is coupled with colloidal silica, and then the resulting product is optically irradiated, thereby obtaining colloidal silica having a carboxylic acid immobilized on its surface. Immobilization of an alkylamine as an organic amine on colloidal silica can be achieved by the method described in JP 2012-211080 A. Specifically, a silane coupling agent having an alkylamine group such as 3-aminopropyltriethoxysilane is coupled with colloidal silica, thereby obtaining colloidal silica having an organic amine immobilized on its surface.

The size (average primary particle size and average secondary particle size), true density, and BET specific surface area of silica can be appropriately controlled by, for example, the choice of the method for producing silica (abrasive grains).

The polishing composition include silica as abrasive grains. The silica content is not particularly limited. However, as described above, the polishing composition of the present invention allows efficient access of silica to an object to be polished even a small amount (low concentration) of the silica is used, which allows efficient polishing of the surface of an object to be polished. Specifically, a content (concentration) of the silica is preferably more than 0% by mass and 8% by mass or less with respect to the whole polishing composition. The lower limit of the content of the silica is more preferably 0.002% by mass or more, even more preferably 0.02% by mass or more, and particularly preferably 0.1% by mass or more with respect to the whole polishing composition. The upper limit of the content of the silica is more preferably less than 8% by mass, even more preferably 5% by mass or less, and particularly preferably 2% by mass or less with respect to the whole polishing composition. In particular, when the silica amount is decreased as described above, the reduction of scratches (defects) caused by collision of abrasive grains to an object to be polished is effectively achieved. The content of the silica is 0.002% by mass or more and 8% by mass or less in one preferred embodiment, 0.02% by mass or more and 5% by mass or less in a more preferred embodiment, 0.1% by mass or more and 2% by mass or less in an even more preferred embodiment with respect to the whole polishing composition. When the content of the silica is within these ranges, both of improvement of the polishing speed and reduction of scratches (defects) are achieved with good balance while cutting the cost. When the polishing composition includes two or more kinds of silica, the content of the silica means their total.

The polishing composition of the present invention preferably includes a dispersion medium for dispersing each component. Examples of the dispersion medium include water; alcohols such as methanol, ethanol, and ethylene glycol; ketones such as acetone; and mixtures thereof, and the like. The dispersion medium preferably contains water. More specifically, according to a preferred embodiment of the present invention, the polishing composition further includes water. According to a more preferred embodiment of the present invention, the dispersion medium is substantially composed of water. The above-described “substantially” means that, as long as the object and effect of the present invention will be achieved, a dispersion medium other than water can be included; more specifically, the dispersion medium includes 90% by mass or more and 100% by mass or less of water and 0% by mass or more and 10% by mass or less of a dispersion medium other than water, preferably includes 99% by mass or more and 100% by mass or less of water and 0% by mass or more and 1% by mass or less of a dispersion medium other than water. Most preferably, the dispersion medium is water. From the viewpoint of preventing inhibition of the action of other components, water containing as less impurity as possible is preferred. Specifically, pure water, ultrapure water, or distilled water prepared by removing impurity ions with an ion exchange resin, and then filtering the water to remove foreign matters are preferred.

One characteristic of the polishing composition of the present invention is that the polishing composition has a pH at 25° C. of less than 6.0. If the pH at 25° C. of the polishing composition is 6.0 or more, the polishing speed decreases, and scratches tend to occur. The pH at 25° C. of the polishing composition is preferably 5.0 or less, and particularly preferably 4.0 or less. The lower limit of the pH at 25° C. of the polishing composition is preferably 1.0 or more, more preferably 2.0 or more, and particularly preferably 3.0 or more. In the present description, unless otherwise specified, “pH” means “pH at 25° C.” The pH at 25° C. of the polishing composition is 1.0 or more and less than 6.0 in a preferred embodiment, 2.0 or more and less than 6.0 in a more preferred embodiment, 3.0 or more and less than 6.0 in an even more preferred embodiment, and 3.0 or more and 4.0 or less in one particularly preferred embodiment. When the polishing composition has such pH, silica (abrasive grains) is stably dispersed. In the present description, the value of pH is measured at 25° C. with a pH meter (model number: LAQUA (registered trademark) manufactured by Horiba, Ltd.).

The above-described pH can be controlled by adding an appropriate amount of a pH adjusting agent. More specifically, the polishing composition may further include a pH adjusting agent. The pH adjusting agent used as necessary for adjusting the pH of the polishing composition to a desired value may be an acid or an alkali, and may be an inorganic compound or an organic compound. Specific examples of the acid include inorganic acids such as sulfuric acid, nitric acid, boric acid, carbonic acid, hypophosphorous acid, phosphorous acid, and phosphoric acid; and organic acids such as carboxylic acid such as formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, and lactic acid, organic sulfuric acid such as methanesulfonic acid, ethanesulfonic acid, and isethionic acid, and organophosphorus acids such as phytic acid and hydroxyethylidene diphosphonic acid. Since the polishing composition according to an aspect of the present invention has a relatively low pH (less than 6.0), in an embodiment, the polishing composition further includes an acid.

Specific examples of the alkali include hydroxides of alkali metals such as potassium hydroxide, amines such as ammonia, ethylenediamine, and piperazine, and quaternary ammonium salts such as tetramethyl ammonium and tetraethyl ammonium. These pH adjusting agents may be used alone or in combination of or two or more of them.

The polishing composition according to an aspect of the present invention may further include, as necessary, other component such as an oxidizing agent, a metal anticorrosive, an antiseptic agent, an antifungal agent, a water-soluble polymer, and an organic solvent for dissolving a slightly soluble organic substance. The oxidizing agent, metal anticorrosive, antiseptic agent, and antifungal agent, which are preferred other components, are described below.

(Oxidizing Agent)

The oxidizing agent which may be included in the polishing composition has an action of oxidizing the surface of an object to be polished, and improves the polishing speed of an object to be polished by the polishing composition.

Examples of the oxidizing agent which can be used include hydrogen peroxide, sodium peroxide, barium peroxide, ozone water, silver (II) salt, iron (III) salt, permanganic acid, chromic acid, dichromic acid, peroxodisulfuric acid, peroxophosphoric acid, peroxosulfuric acid, peroxoboric acid, performic acid, peracetic acid, perbenzoic acid, perphthalic acid, hypochlorous acid, hypobromous acid, hypoiodous acid, chloric acid, chlorous acid, perchloric acid, bromic acid, iodic acid, periodic acid, persulfuric acid, dichloroisocyanuric acid, salts thereof, and the like. These oxidizing agents may be used alone or in combination of two or more of them.

The content of the oxidizing agent in the polishing composition is preferably 0.1 g/L or more, more preferably 1 g/L or more, and even more preferably 3 g/L or more. The increase of the content of the oxidizing agent more improves the polishing speed of an object to be polished by the polishing composition.

The content of the oxidizing agent in the polishing composition is preferably 200 g/L or less, more preferably 100 g/L or less, and even more preferably 40 g/L or less. The decrease of the content of the oxidizing agent reduces the material cost of the polishing composition, and relives the load of the treatment of the polishing composition after polishing, that is, the treatment of waste water. Additionally, it reduces a risk of excessive oxidation of the surface of an object to be polished by the oxidizing agent.

(Metal Anticorrosive)

Inclusion of a metal anticorrosive in the polishing composition further reduces the occurrence of depressions besides wiring during polishing using the polishing composition. Additionally, it also further reduces the occurrence of dishing on the surface of an object to be polished after polishing using the polishing composition.

The metal anticorrosive which can be used is not particularly limited, and is preferably a heterocyclic compound or a surfactant. The number of heterocycle in the heterocyclic compound is not particularly limited. The heterocyclic compound may be a monocyclic compound, or a polycyclic compound having condensed rings. The metal anticorrosive may be used alone, or in combination of two or more of them. The metal anticorrosive may be a commercial product or a synthetic product.

Specific examples of the heterocyclic compound which may be used as a metal anticorrosive include nitrogen-containing heterocyclic compounds such as pyrrole compounds, pyrazole compounds, imidazole compounds, triazole compounds, tetrazole compounds, pyridine compounds, pyrazine compounds, pyridazine compounds, pyrindine compounds, indolyzine compounds, indole compounds, isoindole compounds, indazole compounds, purine compounds, quinolizine compounds, quinoline compounds, isoquinoline compounds, naphthyridine compounds, phthalazine compounds, quinoxaline compounds, quinazoline compounds, cinnoline compounds, pteridine compounds, thiazole compounds, isothiazole compounds, oxazole compounds, isoxazole compounds, and furazan compounds.

(Antiseptic Agent and Antifungal Agent)

Examples of the antiseptic agent and antifungal agent used in the present invention include isothiazoline antiseptic agents such as 2-methyl-4-isothiazoline-3-one and 5-chloro-2-methyl-4-isothiazoline-3-one, p-oxybenzoates, phenoxyethanol, and the like. These antiseptic agents and antifungal agents may be used alone, or in combination of two or more of them.

<Method for Producing Polishing Composition>

The method for producing the polishing composition of the present invention is not particularly limited. For example, the composition can be obtained by mixing abrasive grains and as necessary other components in, for example, a dispersion medium under stirring. More specifically, an aspect of the present invention provides a method for producing a polishing composition used for polishing an object to be polished, including providing silica having a maximum peak temperature of 30° C. or higher and 53° C. or lower in a weight change rate distribution curve obtained by thermogravimetric measurement in a range of 25° C. or higher and 250° C. or lower, mixing the silica with water, and adjusting the pH of the mixture at 25° C. to less than 6.0.

As described above, in order to adjust the maximum peak temperature in a weight change rate distribution curve obtained by thermogravimetric measurement in a range of 25° C. or higher and 250° C. or lower to 30° C. or higher and 53° C. or lower, the surface condition of silica is controlled by, for example, hydrothermal treatment or surface modification.

The temperature during mixing the components is not particularly limited, but is preferably 10 to 40° C., and may be increased for increasing the rate of dissolution. The mixing time is also not particularly limited. As described above, the above-described pH can be adjusted by adding an appropriate amount of a pH adjusting agent.

<Object to be Polished>

In the present invention, an object to be polished is not particularly limited, and examples thereof include metals, an object to be polished having an oxygen atom(s) and a silicon atom(s), an object to be polished having a silicon-silicon bond, and an object to be polished having a nitrogen atom(s) and a silicon atom(s).

Examples of the metal include copper, aluminum, hafnium, cobalt, nickel, titanium, tungsten, and the like.

Examples of an object to be polished having an oxygen atom and a silicon atom include silicon oxide (SiO₂), tetraethyl orthosilicate (TEOS), and the like.

Examples of an object to be polished having a silicon-silicon bond include polysilicon, amorphous silicon, single crystal silicon, n-type doped single-crystal silicon, p-type doped single-crystal silicon, Si alloys such as SiGe, and the like.

Examples of an object to be polished having a nitrogen atom and a silicon atom include those having a silicon-nitrogen bond such as a silicon nitride film and SiCN (silicon carbonitride).

These materials may be used alone or in combination of two or more of them.

Among them, when the object to be polished contains an oxygen atom and a silicon atom, furthermore, when the object to be polished contains a bond between an oxygen atom and a silicon atom, the effect of the present invention is more effectively achieved, and when the object to be polished contains silicon oxide using tetraethyl orthosilicate (TEOS) as a raw material, the effect of the present invention is more effectively achieved. More specifically, according to a preferred embodiment of the present invention, the polishing composition of the present invention is used for polishing an object to be polished containing an oxygen atom and a silicon atom. Furthermore, according to a particularly preferred embodiment of the present invention, the object to be polished is a silicon oxide substrate using tetraethyl orthosilicate as a raw material.

An object to be polished preferably a material containing an oxygen atom and a silicon atom. Even in this case, it may further include other material than that described above. Examples of the other material include silicon nitride (SiN), silicon carbide (SiC), sapphire (Al₂O₃), silicon germanium (SiGe), and the like.

<Polishing Method and Production Method of Substrate>

As described above, the polishing composition according to an aspect of the present invention and the polishing composition produced by the above-described production method is particularly suitably used for polishing of an object to be polished including an oxygen atom and a silicon atom. Accordingly, an aspect of the present invention provides a polishing method including polishing an object to be polished containing an oxygen atom and a silicon atom using the above-described polishing composition, or obtaining a polishing composition by the above-described production method, and polishing the object to be polished using the polishing composition. Additionally, a preferred embodiment of the present invention provides a polishing method including polishing an object to be polished containing tetraethyl orthosilicate (TEOS) using the polishing composition of the present invention, or obtaining a polishing composition by the above-described production method, and polishing the object to be polished using the polishing composition.

As a polishing apparatus, a common polishing apparatus including a polishing table equipped with a holder for holding a substrate and the like having an object to be polished, a motor whose rotation rate is variable, and the like, and allowing attachment of a polishing pad (polishing cloth) to it may be used.

As the polishing pad, for example, a common nonwoven fabric, polyurethane, and a porous fluorocarbon resin may be used without particular limitation. The polishing pad is preferably grooved for retaining a polishing liquid.

The polishing conditions are not particularly limited. For example, the rotation rate of the polishing table (platen) is preferably 10 to 500 rpm, the pressure (polishing pressure) applied to the substrate having an object to be polished is preferably 0.5 to 10 psi. The method for feeding the polishing composition to the polishing pad is also not particularly limited; for example, the polishing composition is continuously fed with a pump or the like. The feeding amount is not limited, but the surface of the polishing pad is preferably constantly covered by the polishing composition according to an aspect of the present invention.

After completion of polishing, the substrate is washed in running water, and the substrate is dried by brushing off water droplets adhered to the substrate with a spin dryer or the like, thereby obtaining a substrate having an oxygen atom and a silicon atom.

The polishing composition of the present invention may be a one-liquid type or a multi-liquid type such as two-liquid type wherein a portion or whole of the polishing composition is mixed at any mixing ratio. When a polishing apparatus including plural channels for feeding the polishing composition is used, two or more polishing compositions which have been previously prepared may be used so as to mix the polishing compositions on the polishing apparatus.

The polishing composition according to an aspect of the present invention may be in a form of a stock solution, and may be prepared by diluting the stock solution of the polishing composition with water. When the polishing composition is the two-liquid type, the order of mixing and dilution is arbitrary; for example, one composition is diluted with water and then mixed, the components are diluted with water concurrently with mixing, or the mixed polishing composition is diluted with water.

### EXAMPLES

The present invention is further described below using the following examples and comparative examples. However, the technical scope of the present invention will not be limited to the following examples only. Unless otherwise specified, “%” and “part” mean “% by mass” and “parts by mass”, respectively. In the following Examples, unless otherwise specified, operations were carried out under the conditions of room temperature (25° C.)/relative humidity of 40 to 50% RH.

The average primary particle size (nm), average secondary particle size (nm), true density (g/cm³), BET specific surface area (m²/g), and TG peak temperature (° C.) of silica (abrasive grains) is measured by the following method.

[Average Particle Size (Nm) of Silica]

The average primary particle size (nm) of silica (abrasive grains) is calculated based on the average of the specific surface area (SA) of silica particles calculated by measuring about 0.2 g of a silica sample three to five times continuously by the BET method, on the assumption that the shape of the silica particles is spherical. The value of the degree of association (average secondary particle size/average primary particle size) can be also calculated from these values.

The average secondary particle size (nm) of silica (abrasive grains) is determined by measuring a silica sample using a particle size distribution analyzer of dynamic light scattering type (UPA-UT151, manufactured by Nikkiso Co., Ltd.). Firstly, abrasive grains are dispersed in pure water, thereby preparing a dispersion having a loading index (dispersion strength of laser) of 0.01. Subsequently, using the dispersion, the value of the volume average particle size My in the UT mode is continuously measured three to five times, and the average of the obtained values was used as the average secondary particle size.

[True Density (g/cm³) of Silica]

The true density (g/cm³) of silica (abrasive grains) is measured by the following method. Specifically, firstly, a silica aqueous solution is placed in a crucible in an amount of about 15 g in terms of the solid content (silica), and moisture is evaporated at about 200° C. using a commercial hot plate. Furthermore, in order to remove moisture remaining in silica cavities, heat treatment is carried out one hour using an electric furnace (kiln, manufactured by Advantech Co., Ltd.) at 300° C., and the dry silica after treatment is ground with a mortar. Subsequently, 10 g of the dry silica prepared above is placed in a 100-ml pycnometer (Wa (g)), the weight of which has been previously measured with a precision balance (GH-202, manufactured by A&D Company, Ltd.), the weight is measured (Wb (g)), then 20 ml of ethanol is added, and deaerated for 30 minutes in a decompressed desiccator. Thereafter, the pycnometer is filled with ethanol, capped, and the weight is measured (Wc (g)). After measuring the weight of silica, the content of the pycnometer is disposed, the pycnometer is filled with ethanol after washing, and the weight is measured (Wd (g)). The true density is calculated from these weights and the temperature (t (° C.)) of the ethanol at the time of measurement according to Formula 1 and Formula 2.

[Formula 1]

Ld=0.80653−0.000867×t Formula 1:

In the formula 1, Ld represents the specific gravity (g/cm³) of ethanol at t° C.

[Formula 2]

Sg−(Wb−Wa)/(Wd−Wc+Wb−Wa)×Ld Formula 2:

In the formula 2, Sg represents the true density (g/cm³) of silica,

Wa represents the weight of pycnometer,

Wb represents the total weight (g) of the sample (dry silica) and pycnometer,

Wc represents the total weight (g) of the sample (dry silica), ethanol, and pycnometer,

Wd represents the total weight (g) of ethanol and pycnometer, and

Ld represents the specific gravity (g/cm³) of ethanol determined by the Formula 1.

[BET Specific Surface Area (m²/g) of Silica]

Specific surface area (m²/g) of silica (abrasive grains) is measured using the BET method. Specifically, the sample (silica) is heated at 105° C. for 12 hours or more to remove moisture. The dried silica is ground in a mortar, about 0.2 g of silica is placed in a previously weighed cell (Wa′ (g)), the weight is measured (Wb′ (g)), and heated at 180° C. for five minutes or more with a heating part of a specific surface area meter (Flowsorb II 2300, manufactured by Shimadzu Co., Ltd.). Thereafter, the sample is mounted on the measurement part, and the adsorption area (A [m²]) under deaeration) is measured. Using the value A, the specific surface area SA [m²/g] is determined by the following formula 3.

[Formula 3]

SA=A/(Wb′−Wa′) Formula 3:

In the Formula 3, SA represents the BET specific surface area (m²/g) of silica;

A represents the adsorption area (m²) under deaeration;

Wa′ represents the weight (g) of cell; and

Wb′ represents the total weight (g) of the sample (dry silica) and cell.

[Thermogravimetric Measurement (TG)]

TG is an analytical method for detecting a weight change of a sample when a temperature of the measurement sample is changed according to a certain program, and a plotted date is obtained as a function of the temperature. Firstly, silica as a measurement sample is dried at 105° C. for 24 hours, free moisture is removed. The dried sample is ground in an agate mortar, about 30 mg of the sample is weighed into an alumina pan, and the measurement is carried out using a TG apparatus (Thermo plus Evo, manufactured by Rigaku Corporation)). α-alumina is used as a standard sample. In the measurement, firstly, the temperature of the measuring part is increased to 150° C. at a rate of 2° C./minute, thereby removing excessive moisture. In this manner, the influence of the difference of an amount of the moisture absorption by the difference of the standing time after drying is excluded. Thereafter, the sample is allowed to stand for 40 minutes in an atmosphere at a relative humidity of 70% RH and 25° C., thereby allowing the sample to absorb moisture. When the temperature of the measuring part is decreased to 25° C., immediately, the temperature of the measuring part is increased to 250° C. at a rate of 1° C./minute, and a heat weight change over time is measured every 0.5 minutes. From the weight change determined by the measurement, a weight change rate per unit area (weight change rate) is calculated. A weight change rate distribution curve is obtained by plotting the weight change rate as the ordinate, and the measurement temperature as the abscissa, followed by Gaussian fitting, and then a bottom temperature of a maximum peak (TG peak temperature) is determined. The weight change rate (ΔW) between the measurement point n−1 (sample weight Wₙ₋₁, measurement temperature Tₙ₋₁) and the next measurement point n (sample weight Wₙ, measurement temperature Tₙ) is the value calculated by the following Formula 4.

[Formula 4]

Weight change rate(ΔW)=(Wₙ−Wₙ₋₁)/((Tₙ−Tₙ₋₁)×SA) Formula 4:

In the Formula 4, Wₙ₋₁ and Tₙ₋₁ represent the sample weight and measured temperature, respectively, at the measurement point n−1:

Wₙ and Tₙ represent the sample weight and measured temperature, respectively, at the measurement point n following the measurement point n−1:

SA represents the BET specific surface area (m²/g) of silica.

### Comparative Example 1

Abrasive grains 1 were prepared as abrasive grains. The abrasive grains 1 are colloidal silica having an average primary particle size of 35 nm, an average secondary particle size of 67 nm, a degree of association of 1.9, a BET specific surface area of 78 m²/g, a true density of 1.80 g/cm³, and a TG peak temperature of 55.0° C. prepared by the sol-gel method. FIG. 2 depicts the weight change rate distribution curve of the abrasive grains 1 (Comparative Example 1) obtained by thermogravimetric measurement.

The abrasive grains 1 were dispersed in a dispersion medium (pure water) under stirring so as to make have a concentration thereof in the composition 1.0% by mass, and lactic acid as a pH adjusting agent was added so as to adjust the pH of the polishing composition to 4.0, thereby preparing a polishing composition (polishing composition 1) (mixing temperature: about 25° C., mixing time: about 10 minutes). The pH of the polishing composition (liquid temperature: 25° C.) was confirmed with a pH meter (model number: LAQUA (registered trademark), manufactured by Horiba, Ltd.).

### Example 1

Polishing composition 2 was prepared in the same manner as in Comparative Example 1, except that abrasive grains 2 obtained by hydrothermal treatment of the abrasive grains 1 under the following conditions. More specifically, 1 kg of the abrasive grains 1 was charged into an autoclave with a band heater (TAS-1, manufactured by Taiatsu Techno Corporation) (silica concentration 19.5% by mass, pH 7.3). In this apparatus, the temperature is controlled with a band heater in absolute contact with the container, and heat is uniformly applied to the sample under stirring in the container. Hydrothermal treatment was carried out by programmed operation under the following conditions: the starting point was room temperature (25° C.), the temperature rising rate was 1.75° C./minute, the maximum temperature was 160° C., the maximum temperature (160° C.) was kept for 1 hour and 45 minutes, and the pressure at the maximum temperature (160° C.) was 0.63 MPa. The abrasive grains after completion of hydrothermal treatment was returned to a room temperature environment immediately so as not to excessively prolong the heating time. The abrasive grains 2 were obtained by the above-described method.

The abrasive grains 2 obtained by the hydrothermal treatment had an average primary particle size of 35 nm, an average secondary particle size of 67 nm, a degree of association of 1.9, a BET specific surface area of 68 m²/g, a true density of 1.80 g/cm³, and a TG peak temperature of 51.0° C. The weight change rate distribution curve of the abrasive grains 2 (Example 1) obtained by thermogravimetric measurement is depicted in FIG. 2.

### Comparative Example 2

Abrasive grains 3 were provided as abrasive grains. The abrasive grains 3 are colloidal silica prepared by the sol-gel method having an average primary particle size of 32 nm, an average secondary particle size of 61 nm, a degree of association of 1.9, a BET specific surface area of 90 m²/g, a true density of 2.10 g/cm³, and a TG peak temperature of 44.5° C.

The abrasive grains 3 were dispersed in a dispersion medium (pure water) under stirring so as to adjust the concentration of the abrasive grains 3 in the composition to 1.0% by mass, and the pH to 8.0, thereby preparing a polishing composition (polishing composition 3) (mixing temperature: about 25° C., mixing time: about 10 minutes). Ammonia was used for adjustment of the pH.

### Example 2

In Comparative Example 2, lactic acid was added as a pH adjusting agent so as to adjust the pH of the polishing composition to 4.0, thereby preparing a polishing composition. A polishing composition 4 was prepared in the same manner as in Comparative Example 2, except that the above-described operation. FIG. 2 depicts the weight change rate distribution curve of the abrasive grains 3 (Example 2) obtained by thermogravimetric measurement.

The polishing composition obtained above was evaluated for the polishing speed and defects (number of scratches) according to the following method. These results are given in Table 1. In Table 1, “TEOS RR” means the polishing speed.

[Polishing Speed]

Using the polishing compositions obtained above, the polishing speed (TEOS RR) during polishing of an object to be polished (TEOS substrate) under the following polishing conditions was measured.

(Polishing Conditions)

Polishing machine: compact desktop polisher (manufactured by Engis Japan Corporation, EJ380IN)

Polishing pad: hard polyurethane pad (manufactured by Nitta Haas Incorporated, IC1000)

Platen (table) rotation rate: 60 [rpm]

Head (carrier) rotation rate: 60 [rpm]

Polishing pressure: 3.0 [psi]

Flow rate of polishing composition (slurry): 100 [ml/min]

Polishing time: 1 [min]

Polishing speed (polishing rate) was evaluated by determining the film thickness of an object to be polished before and after polishing using an optical interference film thickness measurement apparatus (Lambda Ace VM2030, manufactured by SCREEN Holdings, Co., Ltd.), and then dividing the difference by the polishing time (see the following formula).

$$Polishing rate [ Å \text{/} min ] = \frac{\begin{matrix}film thickness [ Å ] before polishing - \\ film thickness [ Å ] after polishing\end{matrix}}{polishing time [ min ]} \qquad [ Formula 5 ]$$

[Defects (Number of Scratches)]

Using the polishing compositions obtained above, defects (the number of scratches) were evaluated according to the following method. Specifically, the number of scratches on the surface of an object to be polished was determined by detecting defects of 0.13 μm or more on the entire wafer surface (excluding 2 mm from the outer periphery) using a defect detector (wafer inspection apparatus) “Surfscan (registered trademark) SP2” manufactured by KLA-TENCOR Corporation. The total number of the detected defects was observed with Review-SEM (RS-6000, manufactured by Hitachi High-Technologies Corporation), thereby counting the number of defects (scratches). The number of defects (scratches) thus obtained was evaluated according to the following evaluation criteria.

(Evaluation Criteria for Number of Scratches)

⊙: The number of defects of 0.13 μm or more is 20 or less

◯: The number of defects of 0.13 μm or more is 21 or more and 30 or less

Δ: The number of defects of 0.13 μm or more is 31 or more and 50 or less

×: The number of defects of 0.13 μm or more is 51 or more

TABLE 1

| | Colloidal silica (abrasive grains) | | | | | | | | | |
|---|---|---|---|---|---|---|---|---|---|---|
| | | | BET | | | | | | | |
| | Primary | Secondary | specific | | | Polishing composition | | | | |
| | particle | particle | surface | True | TG peak | Silica | | pH | | |
| | size | size | area | density | temperature | concentration | | adjusting | TEOS RR | |
| | (nm) | (nm) | (m²/g) | (g/cm³) | (° C.) | (% by mass) | pH | agent | (Å/minute) | Scratch |
| Comparative | 35 | 67 | 78 | 1.80 | 55.0 | 1.0 | 4.0 | Lactic acid | 67 | X |
| Example 1 | | | | | | | | | | |
| Example 1 | 35 | 67 | 68 | 1.80 | 51.0 | 1.0 | 4.0 | Lactic acid | 931 | ◯ |
| Comparative | 32 | 61 | 90 | 2.10 | 44.5 | 1.0 | 8.0 | Ammonia | 20 | X |
| Example 2 | | | | | | | | | | |
| Example 2 | 32 | 61 | 90 | 2.10 | 44.5 | 1.0 | 4.0 | Lactic acid | 1563 | ⊙ |

As is evident from Table 1, the polishing composition of Examples further improves the polishing speed of the TEOS substrate and reduces scratches on the TEOS substrate even at a low silica concentration (1.0% by mass) in comparison with the polishing composition of Comparative Examples.

The present application is based on Japanese Patent Application No. 2016-140629 filed on Jul. 15, 2016, and the disclosure of which is incorporated herein as a whole by reference.

1. A polishing composition comprising silica having a maximum peak temperature of 30° C. or higher and 53° C. or lower in a weight change rate distribution curve obtained by thermogravimetric measurement in a range of 25° C. or higher and 250° C. or lower, and having a pH at 25° C. of less than 6.0.

2. The polishing composition according to claim 1, wherein the silica is colloidal silica.

3. The polishing composition according to claim 1, which further comprises water.

4. The polishing composition according to claim 3, which further comprises an acid.

5. The polishing composition according claim 1, wherein a content of the silica is more than 0% by mass and 8% by mass or less with respect to the whole composition.

6. The polishing composition according to claim 1, wherein a true density of the silica is 1.90 g/cm³ or more.

7. The polishing composition according to claim 1, which is used for polishing an object to be polished comprising an oxygen atom and a silicon atom.

8. A method for producing a polishing composition used for polishing an object to be polished, comprising:
providing silica having a maximum peak temperature of 30° C. or higher and 53° C. or lower in a weight change rate distribution curve obtained by thermogravimetric measurement in a range of 25° C. or higher and 250° C. or lower,
mixing the silica with water, and
adjusting a pH of mixture at 25° C. to less than 6.0.

9. A polishing method comprising:
polishing an object to be polished comprising an oxygen atom and a silicon atom using the polishing composition set forth in claim 1.

10. A polishing method comprising:
obtaining a polishing composition by the production method set forth in claim 8, and
polishing the object to be polished using the polishing composition.
